(19) United States
(12) Patent Application Publication
(10) Pub. No.: US 2024/0170455 A1
(43) Pub. Date: May 23, 2024

(54) SEMICONDUCTOR PACKAGE

(71) Applicant: SAMSUNG ELECTRONICS CO., LTD., Suwon-si (KR)

(72) Inventors: Yonghoe CHO, Suwon-si (KR); Seunghoon YEON, Suwon-si (KR); SeungRyong OH, Suwon-si (KR)

(73) Assignee: SAMSUNG ELECTRONICS CO., LTD., Suwon-si (KR)

(21) Appl. No.: 18/226,529

(22) Filed: Jul. 26, 2023

(30) Foreign Application Priority Data
Nov. 21, 2022 (KR) 10-2022-0156565

(51) Int. Cl. H01L 25/065; H01L 23/00; H01L 23/31

(52) U.S. Cl. CPC H01L 25/0657; H01L 23/3107; H01L 24/08; H01L 24/16; H01L 24/32; H01L 24/73; H01L 2224/08148; H01L 2224/16148; H01L 2224/32145; H01L 2224/73204; H01L 2225/06513; H01L 2225/06544; H01L 2924/1431; H01L 2924/1436; H01L 2924/1437; H01L 2924/1438

(57) ABSTRACT

A semiconductor package is provided that includes: a first semiconductor die, and a second semiconductor die on the first semiconductor die. The first semiconductor die includes a semiconductor substrate, a wiring layer on an active surface of the semiconductor substrate, a redistribution pattern on an inactive surface of the semiconductor substrate, a first passivation layer on the inactive surface of the semiconductor substrate wherein the first passivation layer is on the redistribution pattern and has an opening that exposes a top surface of the redistribution pattern, and a backside pad on the first passivation layer and coupled through the opening to the redistribution pattern. An inner lateral surface of the opening is inclined at an angle of 90 to 105 degrees relative to the top surface of the redistribution pattern. A thickness of the first passivation layer is 0.3 to 0.5 times a thickness of the redistribution pattern.

### CROSS-REFERENCE TO RELATED APPLICATION

This application claims priority under 35 U.S.C § 119 to Korean Patent Application No. 10-2022-0156565, filed on Nov. 21, 2022, in the Korean Intellectual Property Office, the disclosure of which is hereby incorporated by reference in its entirety.

### BACKGROUND

Embodiments of the present disclosure relate to a semiconductor package, and more particularly, to a stacked semiconductor package in which a plurality of semiconductor chips are stacked on a substrate.

A semiconductor device generally has an electrical connection structure, such as solder ball or bump, for electrical connection with another semiconductor device or a printed circuit board. Accordingly, it is required that the semiconductor device has an electrical connection structure capable of accomplishing stable electrical connection.

With the development of electronic industry, electronic products have increasingly demanded high performance, high speed, and compact size. To meet the trend, there has recently been developed a packaging technology in which a plurality of semiconductor chips are mounted in a single package.

Portable devices have been increasingly demanded in recent electronic product markets, and as a result, it has been ceaselessly required for reduction in size and weight of electronic parts mounted in the portable devices. In order to accomplish the reduction in size and weight of the electronic parts, there is a need for technology to integrate a number of individual devices into a single package as well as technology to reduce individual sizes of mounting parts. Various problems occur due to an increase in stacking number of devices.

Semiconductor devices have been rapidly developed to increase the number of electrode terminals and to decrease a pitch between the electrode terminals. Therefore, studies have increasingly been conducted on compactness of semiconductor devices. Semiconductor devices generally have electrical connection terminals, such as solder balls or bumps, for electrical connections with other electronic devices or printed circuit boards. It is required that connection terminals of semiconductor devices have high reliability.

### SUMMARY

Some embodiments of present disclosure provide a compact-sized semiconductor package.

Some embodiments of the present disclosure provide a semiconductor package with improved thermal radiation pattern.

Some embodiments of the present disclosure provide a semiconductor package with enhanced electrical properties.

According to embodiments of the present disclosure, a semiconductor package is provided. The semiconductor package includes: a first semiconductor die; and a second semiconductor die on the first semiconductor die. The first semiconductor die includes: a semiconductor substrate; a wiring layer on an active surface of the semiconductor substrate; a redistribution pattern on an inactive surface of the semiconductor substrate; a first passivation layer on the inactive surface of the semiconductor substrate, wherein the first passivation layer is on the redistribution pattern and has an opening that exposes a top surface of the redistribution pattern; and a backside pad on the first passivation layer and coupled through the opening to the redistribution pattern, wherein an inner lateral surface of the opening is inclined at an angle of 90 degrees to 105 degrees relative to the top surface of the redistribution pattern, and wherein a thickness of the first passivation layer is 0.3 times to 0.5 times a thickness of the redistribution pattern.

According to embodiments of the present disclosure, a semiconductor package is provided. The semiconductor package includes a first semiconductor die including: a semiconductor substrate; a plurality of through vias that vertically penetrate the semiconductor substrate; a plurality of redistribution patterns on a rear surface of the semiconductor substrate and connected to the through vias; a first passivation layer on the rear surface of the semiconductor substrate and on the plurality of redistribution patterns; and a plurality of pads on the first passivation layer. The semiconductor package further includes: a second semiconductor die on the first semiconductor die, wherein the second semiconductor die is mounted on the plurality of pads; a molding layer on a rear surface of the second semiconductor die, wherein the molding layer surrounds the second semiconductor die in a horizontal direction of the semiconductor package; and a plurality of external terminals on a front surface of the first semiconductor die. Each of the plurality of pads includes: a pad part on the first passivation layer; and a via part that extends from a bottom surface of the pad part and penetrates the first passivation layer such as to connect with a respective one of the plurality of redistribution patterns, wherein the via part has a pillar shape that has a width that is constant, and wherein the first passivation layer includes a silicon nitride layer and a silicon oxide layer.

According to embodiments of the present disclosure, a semiconductor package is provided. The semiconductor package includes: a first semiconductor die; and a second semiconductor die on the first semiconductor die. The first semiconductor die includes: a semiconductor substrate; a wiring layer on an active surface of the semiconductor substrate; a first passivation layer on an inactive surface of the semiconductor substrate; a redistribution pattern on the first passivation layer; a second passivation layer on the first passivation layer, the second passivation layer on the redistribution pattern and having an opening that exposes a top surface of the redistribution pattern; and a backside pad on the second passivation layer and coupled through the opening to the redistribution pattern, wherein a thickness of the second passivation layer is less than a thickness of the redistribution pattern, wherein the thickness of the second passivation layer is constant on the semiconductor substrate, and wherein the second passivation layer includes a silicon nitride layer and a silicon oxide layer.

### BRIEF DESCRIPTION OF DRAWINGS

FIG. 1 illustrates a cross-sectional view showing a semiconductor package according to some embodiments of the present disclosure.

FIG. 2 illustrates an enlarged view showing section A of FIG. 1.

FIG. 3 illustrates an enlarged view showing section A of FIG. 1.

FIG. 4 illustrates an enlarged view showing section C of FIG. 2.

FIG. 5 illustrates an enlarged view showing section D of FIG. 2.

FIG. 6 illustrates an enlarged view showing section D of FIG. 2.

FIG. 7 illustrates an enlarged view showing section B of FIG. 1.

FIG. 8 illustrates an enlarged view showing section A of FIG. 1.

FIG. 9 illustrates an enlarged view showing section A of FIG. 1.

FIG. 10 illustrates an enlarged view showing section E of FIG. 9.

FIG. 11 illustrates a cross-sectional view showing a semiconductor package according to some embodiments of the present disclosure.

### DETAILED DESCRIPTION

The following will now describe a semiconductor package according to non-limiting example embodiments the present disclosure with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

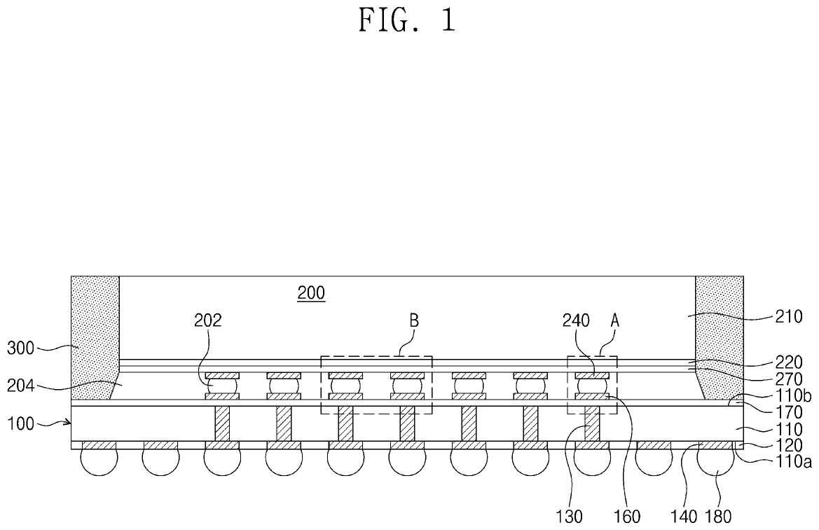

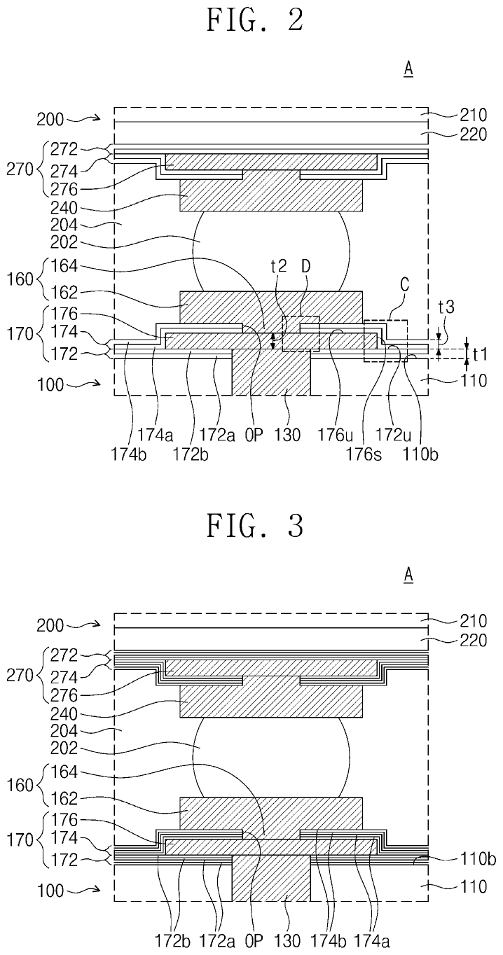

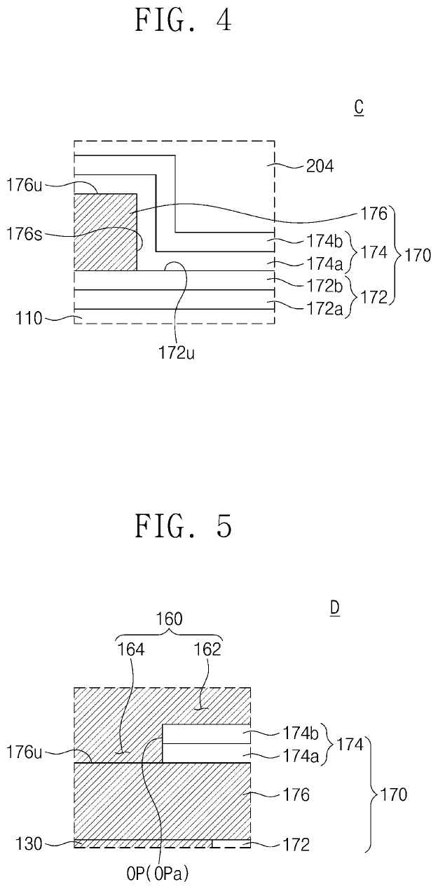

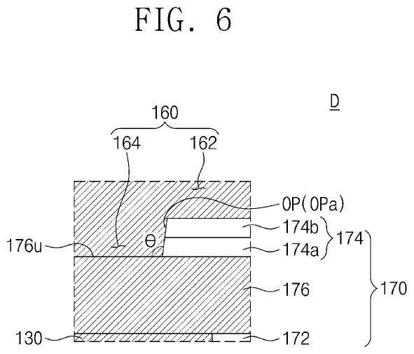

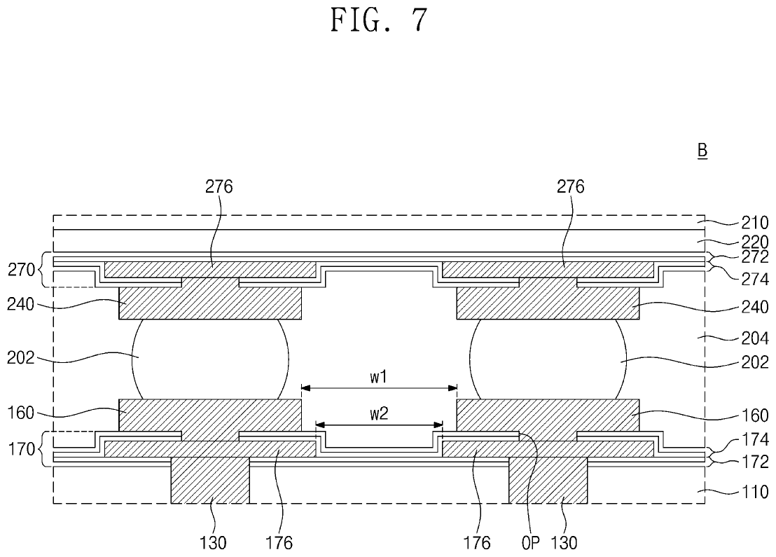

FIG. 1 illustrates a cross-sectional view showing a semiconductor package according to some embodiments of the present disclosure. FIGS. 2 and 3 illustrate enlarged views showing section A of FIG. 1. FIG. 4 illustrates an enlarged view showing section C of FIG. 2. FIGS. 5 and 6 illustrate enlarged views showing section D of FIG. 2. FIG. 7 illustrates an enlarged view showing section B of FIG. 1.

A semiconductor package according to some embodiments of the present disclosure may be a stacked package in which vias are included. For example, semiconductor dies of a same type may be stacked on a base substrate, and the semiconductor dies may be electrically connected to each other through vias that penetrate therethrough. The semiconductor dies may be coupled to each other through their pads that face each other.

Referring to FIG. 1, a base substrate 100 may be provided. The base substrate 100 may include an integrated circuit therein. The base substrate 100 may be a first semiconductor chip that includes an electronic element such as a transistor. For example, the base substrate 100 may be a wafer-level die formed of a semiconductor such as silicon (Si). FIG. 1 shows that the base substrate 100 is a first semiconductor die, but embodiments of the present disclosure are not limited thereto. According to some embodiments of the present disclosure, the base substrate 100 may be a substrate, such as a printed circuit board (PCB), which does not include an electronic device such as a transistor. A silicon wafer may have a thickness less than a thickness of a printed circuit board (PCB). The following will discuss an example in which the base substrate 100 is the first semiconductor die.

The base substrate 100 (e.g., the first semiconductor die) may include a first semiconductor substrate 110, a first circuit layer 120, a first through via 130, a first lower pad 140, a first upper pad 160, and a first redistribution layer 170.

The first semiconductor substrate 110 may include a semiconductor material. For example, the first semiconductor substrate 110 may be a monocrystalline silicon (Si) substrate. The first semiconductor substrate 110 may have a first surface 110a and a second surface 10b that are opposite to each other. The first surface 10a may be a front surface of the first semiconductor substrate 110, and the second surface 110b may be a rear surface of the first semiconductor substrate 110. In the present disclosure, the first surface 110a of the first semiconductor substrate 110 may be defined to indicate a surface on which semiconductor elements are formed or mounted or connection lines and pads are formed, and the second surface 10b of the first semiconductor substrate 110 may be defined to indicate a surface opposite to the first surface 11a. The first surface 10a of the first semiconductor substrate 110 may be a bottom surface of the first semiconductor substrate 110. For example, a bottom surface of the first semiconductor substrate 110 may be an active surface, and a top surface of the first semiconductor substrate 110 may be an inactive surface.

The first circuit layer 120 may be provided on the first surface 110a of the first semiconductor substrate 110. The first circuit layer 120 may include the integrated circuit. For example, the first circuit layer 120 may be a memory circuit, a logic circuit, or a combination thereof. For example, the base substrate 100 may be an application processor (AP) chip or a memory chip. For another example, the base substrate 100 may include a power management integrated circuit (PMIC). The first circuit layer 120 may include an electronic element such as a transistor, a dielectric pattern, and a connection pattern.

The first through via 130 may vertically penetrate the first semiconductor substrate 110. For example, the first through via 130 may connect the first circuit layer 120 to a top surface of the first semiconductor substrate 110. The first through via 130 and the first circuit layer 120 may be electrically connected to each other. The first through via 130 may be provided in plural. A dielectric layer (not shown) may be provided to surround the first through via 130. For example, the dielectric layer (not shown) may include at least one selected from silicon oxide (SiO), silicon nitride (SiN), silicon oxynitride (SiON), and low-k dielectrics.

The first lower pad 140 may be disposed on the first surface 110a of the first semiconductor substrate 110. For example, the first lower pad 140 may be exposed at a bottom surface of the first circuit layer 120. A bottom surface of the first lower pad 140 may be substantially coplanar with a bottom surface of the first circuit layer 120. For example, the bottom surface of the first lower pad 140 may be substantially the same as the bottom surface of the dielectric pattern of the first circuit layer 120.

Embodiments of the present disclosure, however, are not limited thereto. Differently from that shown in FIG. 1, the first lower pad 140 may be positioned on the bottom surface of the first circuit layer 120, and may protrude from the bottom surface of the first circuit layer 120. The first lower pad 140 may be electrically connected to the first circuit layer 120. The first lower pad 140 may be provided in plural. The first lower pad 140 may be a front pad of the base substrate 100 (e.g., the first semiconductor die). The first lower pad 140 may include a metallic material, such as copper (Cu), aluminum (Al), and/or nickel (Ni).

The base substrate 100 may further include a lower passivation layer (not shown). The lower passivation layer (not shown) may be disposed on a bottom surface of the base substrate 100, covering the first circuit layer 120. The first circuit layer 120 may be protected by the lower passivation layer (not shown). The lower passivation layer (not shown) may expose the first lower pad 140. The lower passivation layer (not shown) may be a dielectric coating layer including epoxy resin. Alternatively, the lower passivation layer (not shown) may include silicon oxide (SiO), silicon nitride (SiN), silicon oxynitride (SiON), or silicon carbonitride (SiCN).

An external terminal 180 may be provided on the bottom surface of the base substrate 100. The external terminal 180 may be disposed on the first lower pad 140. The external terminal 180 may be electrically connected to the first circuit layer 120 and the first through via 130. Alternatively or additionally, the external terminal 180 may be disposed below the first through via 130. In this case, the first through via 130 may penetrate the first circuit layer 120 to be exposed at the bottom surface of the first circuit layer 120, and the external terminal 180 may be directly coupled to the first through via 130.

The external terminal 180 may be provided in plural. In this case, the plurality of the plurality of the external terminal 180 may be correspondingly coupled to a plurality of the first lower pad 140. The external terminal 180 may be an alloy that includes at least one selected from tin (Sn), silver (Ag), copper (Cu), nickel (Ni), bismuth (Bi), indium (In), antimony (Sb), and cerium (Ce). The plurality of the external terminal 180 may include solder balls or solder bumps, and based on type of the plurality of the external terminal 180, a semiconductor package may be provided in the form of one of a ball grid array (BGA) type, a fine ball-grid array (FBGA) type, and a land grid array (LGA) type.

The first upper pad 160 may be disposed on the second surface 110b of the first semiconductor substrate 110. The first upper pad 160 may be electrically connected to the first through via 130. The first upper pad 160 may be provided in plural. In this case, the plurality of the first upper pad 160 may be correspondingly coupled to a plurality of the first through via 130, and an arrangement of the plurality of the first upper pad 160 may conform to an arrangement of the plurality of the first through via 130. Embodiments of the present disclosure, however, are not limited thereto, and the arrangement of the plurality of the first upper pad 160 may depend on a configuration of the first redistribution layer 170 provided between the plurality of the first upper pad 160 and the plurality of the first through via 130. The first upper pad 160 may be coupled through the first through via 130 to the first circuit layer 120. The first upper pad 160 may be a backside pad of the base substrate 100 (e.g., the first semiconductor die). The first upper pad 160 may include a metallic material, such as copper (Cu), aluminum (Al), and/or nickel (Ni).

The first redistribution layer 170 may be provided between the first upper pad 160 and the first through via 130. The first redistribution layer 170 may cover the second surface 110b of the first semiconductor substrate 110. The first upper pad 160 may be disposed on a top surface of the first redistribution layer 170. The first redistribution layer 170 may be provided either to redistribute the first through via 130 and the first upper pad 160 or to protect the second surface 110b of the first semiconductor substrate 110. The first redistribution layer 170 may include passivation layers (e.g., a first passivation layer 172 and a second passivation layer 174) and a first redistribution pattern 176 buried in the passivation layers. The passivation layers may include a first passivation layer 172 and a second passivation layer 174.

The first passivation layer 172 may cover the second surface 110b of the first semiconductor substrate 110. The first through via 130 may penetrate the first semiconductor substrate 110 and the first passivation layer 172 to be exposed at a top surface of the first passivation layer 172. A top surface of the via 130 may be coplanar with the top surface of the first passivation layer 172. The first passivation layer 172 may have a first thickness t1 of about 0.5 μm to about 2 μm. The first passivation layer 172 may include multiple layers. For example, as shown in FIG. 2, the first passivation layer 172 may include multiple layers, including a silicon nitride (SiN) layer 172a and a silicon oxide (SiO) layer 172b such that the silicon oxide layer 172b is stacked on the silicon nitride layer 172a. Alternatively, the first passivation layer 172 may have a structure in which the silicon nitride layer 172a is stacked on the silicon oxide layer 172b.

FIG. 2 depicts that the first passivation layer 172 has a two-layered structure, but embodiments of the present disclosure are not limited thereto. As shown in FIG. 3, the first passivation layer 172 may have a four-layered structure in which one or more of the silicon nitride layer 172a and one or more of the silicon oxide layer 172b are alternately stacked. Alternatively, the first passivation layer 172 may have a three, five, or more-layered structure including one or more of the silicon nitride layer 172a and one or more of the silicon oxide layer 172b.

The first redistribution pattern 176 may be disposed on the first passivation layer 172. The first redistribution pattern 176 may be coupled to the first through via 130. The first redistribution pattern 176 may be provided in plural. In this case, the plurality of the first redistribution pattern 176 may be correspondingly coupled to a plurality of the first through via 130, and an arrangement of the plurality of the first redistribution pattern 176 may conform to an arrangement of the plurality of the first through via 130. The first redistribution pattern 176 may be coupled through the first through via 130 to the first circuit layer 120. The first redistribution pattern 176 may have a second thickness t2 greater than the first thickness t1 of the first passivation layer 172. The first thickness t1 of the first passivation layer 172 may be about 0.3 times to about 0.5 times the second thickness t2 of the first redistribution pattern 176. The first redistribution pattern 176 may include a metallic material, such as copper (Cu), aluminum (Al), and/or nickel (Ni).

The second passivation layer 174 may be disposed on the first passivation layer 172. The second passivation layer 174 may cover the top surface of the first passivation layer 172. On the first passivation layer 172, the second passivation layer 174 may cover the first redistribution pattern 176. As shown in FIG. 4, the second passivation layer 174 may conformally cover the first redistribution pattern 176 and a top surface 172u of the first passivation layer 172. For example, the second passivation layer 174 may have a third thickness t3 that is substantially constant irrespective of position on the first semiconductor substrate 110.

For example, the third thickness t3 of the second passivation layer 174 may be constant on the top surface 172u of the first passivation layer 172, a lateral surface 176s of the first redistribution pattern 176, and a top surface 176u of the first redistribution pattern 176. The third thickness t3 of the second passivation layer 174 may be about 0.3 times to about 0.5 times the second thickness t2 of the first redistribution pattern 176. The third thickness t3 of the second passivation layer 174 may range from about 0.5 μm to about 2 μm. The second passivation layer 174 may include multiple layers. For example, as shown in FIG. 2, the second passivation layer 174 may include multiple layers, including a silicon nitride (SiN) layer 174a and a silicon oxide (SiO) layer 174b, wherein the silicon oxide layer 174b is stacked on the silicon nitride layer 174a.

Alternatively, the second passivation layer 174 may have a structure in which a silicon nitride layer 174a is stacked on the silicon oxide layer 174b. FIG. 2 depicts that the second passivation layer 174 has a two-layered structure, but embodiments of the present disclosure are not limited thereto. As shown in FIG. 3, the second passivation layer 174 may have a four-layered structure in which one or more of the silicon nitride layer 174a and one or more of the silicon oxide layer 174b are alternately stacked. Alternatively, the second passivation layer 174 may have a three, five, or more-layered structure including one or more of the silicon nitride layer 174a and one or more of the silicon oxide layer 174b.

According to some embodiments of the present disclosure, the first passivation layer 172 and the second passivation layer 174, included in the first redistribution layer 170, may have a small thickness. For example, a thickness of the first passivation layer 172 and the second passivation layer 174 may be less than a thickness of the first redistribution pattern 176 of the first redistribution layer 170. Therefore, heat shielding by the first passivation layer 172 and the second passivation layer 174 may be less likely to occur in a semiconductor package, heat generated from the base substrate 100 may easily be discharged upwards from the base substrate 100 (e.g., the first semiconductor die), and heat generated from the second semiconductor die 200 positioned on the base substrate 100 may easily be discharged downwards through the base substrate 100. In addition, it may be possible to provide a thin compact-sized semiconductor package.

Referring to FIGS. 1, 2, and 5, the second passivation layer 174 may have an opening OP. The opening OP may be positioned on the first redistribution pattern 176. The opening OP may vertically overlap the second passivation layer 174 to expose a portion of the top surface 176u of the first redistribution pattern 176. The opening OP may have an inner sidewall OPa perpendicular to the top surface 176u of the first redistribution pattern 176, and the inner sidewall OPa may be defined by an inner sidewall of the second passivation layer 174 that forms the opening OP.

Alternatively, as shown in FIG. 6, the inner sidewall OPa of the opening OP may be inclined relative to the top surface 176u of the first redistribution pattern 176. For example, the opening OP may have a tapered shape whose width increases with an increasing distance from the top surface 176u of the first redistribution pattern 176. There may be an angle θ, which is not large, between the inner sidewall OPa of the opening OP and the top surface 176u of the first redistribution pattern 176. For example, the angle θ between the inner sidewall OPa of the opening OP and the top surface 176u of the first redistribution pattern 176 may be in a range of about 90 degrees to about 105 degrees.

There may be no or negligible difference in width between bottom and top ends of the opening OP. The opening OP may have a width of about 1 μm to about 10 μm. The opening OP may be provided in plural. In this case, the plurality of the opening OP may be provided on a plurality of the first redistribution pattern 176.

The first upper pad 160 may be disposed on the second passivation layer 174. The first upper pad 160 may have a damascene structure. For example, the first upper pad 160 may include a pad part 162 and a via part 164 that protrudes from a bottom surface of the pad part 162.

The pad part 162 may be positioned on a top surface of the second passivation layer 174. For example, the pad part 162 may protrude from the top surface of the second passivation layer 174, and may have a plate shape that horizontally extends on the top surface of the second passivation layer 174. The pad part 162 may be provided to allow the base substrate 100 to receive another semiconductor die, an electronic device, or an electronic product that is mounted on the pad part 162.

The via part 164 may extend from the bottom surface of the pad part 162. The via part 164 may pass through the opening OP to penetrate the second passivation layer 174, thereby being connected to the first redistribution pattern 176. Based on a shape of the opening OP, the via part 164 may have a pillar shape whose width is constant. Alternatively, when the opening OP has a tapered shape as shown in the embodiment illustrated in FIG. 6, the via part 164 may have a tapered pillar shape whose width increases with an increasing distance from a top surface of the first redistribution pattern 176. The width of the via part 164 may range from about 1 μm to about 10 μm.

According to some embodiments of the present disclosure, the via part 164 of the first upper pad 160 may have a pillar shape whose width is constant and/or a tapered pillar shape whose lateral surface has a small inclination angle. Therefore, there may be no or small difference in width between a bottom surface of the via part 164 in contact with the first redistribution pattern 176 and a top surface of the via part 164 in contact with the pad part 162, and the first upper pad 160 may have a small width. Accordingly, the first upper pad 160 may have an occupied area, and a semiconductor package may have a compact size, an increased wiring density, and improved electrical properties.

As shown in FIG. 7, when the first upper pad 160 is provided in plural, the plurality of the first upper pad 160 may have a pitch (or period) of about 15 μm to about 25 μm. For example, a width of each first upper pad 160 may range from about 9 μm to about 15 μm, and an interval w1 between neighboring ones of the plurality of the first upper pad 160 may range from about 7 μm to about 12 μm. The first redistribution pattern 176 of the first redistribution layer 170 may also be provided in plural, and an interval w2 between neighboring ones of the plurality of the first redistribution pattern 176 may range from about 5 μm to about 9 μm.

According to some embodiments of the present disclosure, as the second passivation layer 174 is provided to have a small thickness and to conformally cover the plurality of the first redistribution pattern 176, the plurality of the first redistribution pattern 176 may be provided to have a small interval therebetween, and the plurality of the first upper pad 160 may be provided to have a small interval therebetween. Therefore, the base substrate 100 (e.g., the first semiconductor die) may be provided to have an increased wiring density, and a semiconductor package may be provided to have a compact size.

The second semiconductor die 200 may be provided on the base substrate 100. The second semiconductor die 200 may include a second semiconductor substrate 210, a second circuit layer 220, a second lower pad 240, and a second redistribution layer 270.

The second semiconductor substrate 210 may include a semiconductor material. For example, the second semiconductor substrate 210 may be a monocrystalline silicon (Si) substrate. The second semiconductor substrate 210 may have a top surface and a bottom surface that are opposite to each other. The bottom surface of the second semiconductor substrate 210 may be a front surface of the second semiconductor substrate 210, and the top surface of the second semiconductor substrate 210 may be a rear surface of the second semiconductor substrate 210. For example, the bottom surface of the second semiconductor substrate 210 may be an active surface, and the top surface of the second semiconductor substrate 210 may be an inactive surface.

The second circuit layer 220 may be provided on the bottom surface of the second semiconductor substrate 210. The second circuit layer 220 may include an integrated circuit. For example, the second circuit layer 220 may include a memory circuit. The second semiconductor die 200 may be a memory chip. Alternatively, the second circuit layer 220 may be a logic circuit. The second circuit layer 220 may include an electronic element such as a transistor, a dielectric pattern, and a connection pattern.

The second lower pad 240 may be disposed on the bottom surface of the second semiconductor substrate 210. The second lower pad 240 may be disposed on a bottom surface of the second circuit layer 220. The second lower pad 240 may be coupled to the second circuit layer 220. The second lower pad 240 may be provided in plural. The second lower pad 240 may be a front pad of the second semiconductor die 200. The second lower pad 240 may include a metallic material, such as copper (Cu), aluminum (Al), and/or nickel (Ni).

The second redistribution layer 270 may be provided between the second lower pad 240 and the second circuit layer 220. The second redistribution layer 270 may cover the bottom surface of the second circuit layer 220. The second circuit layer 220 may be provided either to redistribute the second circuit layer 220 and the second lower pad 240, or to protect the second circuit layer 220. The second redistribution layer 270 may include passivation layers (e.g., a third passivation layer 272 and a fourth passivation layer 274) and a second redistribution pattern 276 buried in the passivation layers. The passivation layers may include a third passivation layer 272 and a fourth passivation layer 274.

The third passivation layer 272 may cover the bottom surface of the second circuit layer 220. The third passivation layer 272 may have a thickness of about 0.5 μm to about 2 μm. The third passivation layer 272 include multiple layers. For example, as shown in FIG. 2, the third passivation layer 272 may include multiple layers, including a silicon nitride (SiN) layer and a silicon oxide (SiO) layer, wherein the silicon oxide layer is stacked on the silicon nitride layer. As another example, the third passivation layer 272 may have a structure in which a silicon nitride layer is stacked on a silicon oxide layer.

FIG. 2 depicts that the third passivation layer 272 has a two-layered structure, but embodiments of the present disclosure are not limited thereto. As shown in FIG. 3, the third passivation layer 272 may have a four-layered structure in which one or more silicon nitride layers and one or more silicon oxide layers are alternately stacked. Alternatively, the third passivation layer 272 may have a three, five, or more-layered structure including one or more silicon nitride layers and one or more silicon oxide layers.

The second redistribution pattern 276 may be disposed on the third passivation layer 272. The second redistribution pattern 276 may be electrically connected to the second circuit layer 220. The second redistribution pattern 276 may be provided in plural. The second redistribution pattern 276 may have a thickness greater than a thickness of the third passivation layer 272. The thickness of the third passivation layer 272 may be about 0.3 times to about 0.5 times the thickness of the second redistribution pattern 276. The second redistribution pattern 276 may include a metallic material, such as copper (Cu), aluminum (Al), and/or nickel (Ni).

The fourth passivation layer 274 may be disposed on the third passivation layer 272. The fourth passivation layer 274 may cover a bottom surface of the third passivation layer 272. On the third passivation layer 272, the fourth passivation layer 274 may cover the second redistribution pattern 276. The fourth passivation layer 274 may conformally cover the second redistribution pattern 276 and the bottom surface of the third passivation layer 272. For example, the fourth passivation layer 274 may have a thickness that is substantially constant irrespective of position on the second semiconductor substrate 210.

The thickness of the fourth passivation layer 274 may be constant on the bottom surface of the third passivation layer 272, a lateral surface of the second redistribution pattern 276, and a bottom surface of the second redistribution pattern 276. The thickness of the fourth passivation layer 274 may be about 0.3 times to about 0.5 times the thickness of the second redistribution pattern 276. The thickness of the fourth passivation layer 274 may range from about 0.5 μm to about 2 μm. The fourth passivation layer 274 may include multiple layers. For example, as shown in FIG. 2, the fourth passivation layer 274 may include multiple layers, including a silicon nitride (SiN) layer and a silicon oxide (SiO) layer, wherein the silicon oxide layer is stacked on the silicon nitride layer.

As another example, the fourth passivation layer 274 may have a structure in which the silicon nitride layer is stacked on the silicon oxide layer. FIG. 2 depicts that the fourth passivation layer 274 has a two-layered structure, but embodiments of the present disclosure are not limited thereto. As shown in FIG. 3, the fourth passivation layer 274 may have a four-layered structure in which one or more silicon nitride layers and one or more silicon oxide layers are alternately stacked. Alternatively, the fourth passivation layer 274 may have a three, five, or more-layered structure including one or more silicon nitride layers and one or more silicon oxide layers.

Referring to FIGS. 1, 2, and 5, the fourth passivation layer 274 may have an opening. The opening may be positioned on the second redistribution pattern 276. The opening may vertically penetrate the fourth passivation layer 274 to partially expose a top surface of the second redistribution pattern 276. The opening may have an inner sidewall perpendicular to the top surface of the second redistribution pattern 276, and the inner sidewall may be defined by an inner sidewall of the fourth passivation layer 274 that forms the opening.

Alternatively, as shown in FIG. 6, the inner sidewall of the opening may be inclined relative to the top surface of the second redistribution pattern 276. For example, the opening may have a tapered shape whose width increases with an increasing distance from the top surface of the second redistribution pattern 276. An angle θ between the inner sidewall of the opening and the top surface of the second redistribution pattern 276 may be about 90 degrees to about 105 degrees. The width of the opening may range from about 1 μm to about 10 μm. The opening may be provided in plural. In this case, the plurality of openings may be provided on a plurality of the second redistribution pattern 276.

The second lower pad 240 may be disposed on the fourth passivation layer 274. The second lower pad 240 may have a damascene structure. For example, the second lower pad 240 may include a pad part and a via part that protrudes from a top surface of the pad part.

The pad part may be positioned on a bottom surface of the fourth passivation layer 274. For example, the pad part may have a plate shape that horizontally extends on the bottom surface of the fourth passivation layer 274.

The via part may extend from the top surface of the pad part. The via part may pass through the opening defined by the fourth passivation layer 274 to come into connection with the second redistribution pattern 276. Based on a shape of the opening, the via part may have a pillar shape whose width is constant. Alternatively, when the opening has a tapered shape as shown in the embodiment illustrated in FIG. 6, the via part may have a tapered pillar shape whose width increases with an increasing distance from the top surface of the second redistribution pattern 276. The width of the via part may range from about 1 μm to about 10 μm.

FIGS. 1 and 2 depict that the second redistribution layer 270 is provided between the second lower pad 240 and the second circuit layer 220, but embodiments of the present disclosure are not limited thereto. According to some embodiments, the second lower pad 240 may be a portion of the connection pattern exposed on a bottom surface of the dielectric pattern of the second circuit layer 220. For example, the second lower pad 240 may be a component provided in the second circuit layer 220, and the second redistribution layer 270 may not be provided between the second circuit layer 220 and the second lower pad 240. The following description will focus on the embodiment illustrated in FIGS. 1 and 2.

The second semiconductor die 200 may be mounted on the base substrate 100. (e.g., the first semiconductor die). For example, the second semiconductor die 200 may be disposed on the base substrate 100. The second semiconductor die 200 may be disposed face-down on the base substrate 100. The first upper pad 160 of the base substrate 100 may be vertically aligned with the second lower pad 240 of the second semiconductor die 200.

The second semiconductor die 200 may be flip-chip mounted on the base substrate 100. For example, a die connection terminal 202 may be provided on the second lower pad 240. The second semiconductor die 200 may be aligned on the base substrate 100 so as to allow the die connection terminal 202 to face a top surface of the first upper pad 160, and the die connection terminal 202 may be coupled to the first upper pad 160. The die connection terminal 202 may connect the first upper pad 160 to the second lower pad 240. The die connection terminal 202 may be provided in plural. For example, each of the first upper pad 160 and the second lower pad 240 may be provided in plural, and each of the plurality of the die connection terminal 202 may connect one of the plurality of the first upper pad 160 to one of the plurality of the second lower pad 240. The die connection terminal 202 may include a solder ball or a solder bump. The die connection terminal 202 may be an alloy that includes at least one selected from tin (Sn), silver (Ag), copper (Cu), nickel (Ni), bismuth (Bi), indium (In), antimony (Sb), and cerium (Ce).

An underfill layer 204 may be provided between the base substrate 100 and the second semiconductor die 200. The underfill layer 204 may fill a space between the base substrate 100 and the second semiconductor die 200. The underfill layer 204 may surround the die connection terminal 202.

A molding layer 300 may be provided on the base substrate 100. The molding layer 300 may cover a top surface of the base substrate 100. The molding layer 300 may surround the second semiconductor die 200. For example, the molding layer 300 may cover a lateral surface of the second semiconductor die 200. The molding layer 300 may protect the second semiconductor die 200. The molding layer 300 may include a dielectric material. For example, the molding layer 300 may include an epoxy molding compound (EMC). According to embodiments, the molding layer 300 may be formed to cover the second semiconductor die 200. For example, the molding layer 300 may cover a rear surface of the second semiconductor die 200.

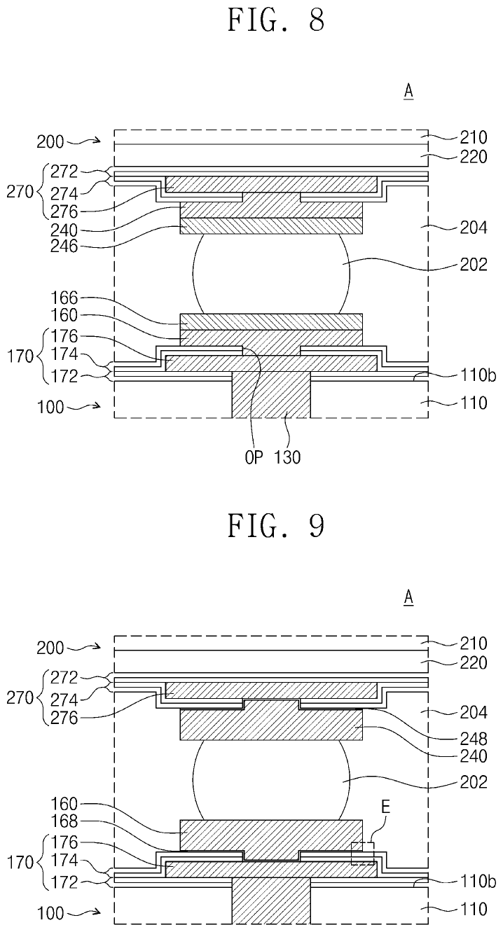

FIG. 8 illustrates an enlarged view showing section A of FIG. 1.

Referring to FIGS. 1 and 8, the first upper pad 160 may have a first under-bump part 166 provided thereon. The first under-bump part 166 may cover the top surface of the first upper pad 160. The first under-bump part 166 may have a width that is the same as a width of the first upper pad 160. For example, a lateral surface of the first under-bump part 166 may be aligned with a lateral surface of the first upper pad 160. The first under-bump part 166 may include the same material as a material of the first upper pad 160. For example, the first under-bump part 166 may include a metallic material, such as copper (Cu), aluminum (Al), and/or nickel (Ni). According to some embodiments, the first under-bump part 166 may include a different material from a material of the first upper pad 160. For example, the first under-bump part 166 may include a metallic material, such as gold (Au), silver (Ag), or tungsten (W).

The second lower pad 240 may have a second under-bump part 246 provided thereunder. The second under-bump part 246 may cover a bottom surface of the second lower pad 240. The second under-bump part 246 may have a width that is the same as a width of the second lower pad 240. For example, a lateral surface of the second under-bump part 246 may be aligned with a lateral surface of the second lower pad 240. The second under-bump part 246 may include the same material as a material of the second lower pad 240. For example, the second under-bump part 246 may include a metallic material, such as copper (Cu), aluminum (Al), and/or nickel (Ni). According to some embodiments, the second under-bump part 246 may include a different material from a material of the second lower pad 240. For example, the second under-bump part 246 may include a metallic material, such as gold (Au), silver (Ag), or tungsten (W).

The die connection terminal 202 may be provided between the first under-bump part 166 and the second under-bump part 246. The die connection terminal 202 may connect the first under-bump part 166 to the second under-bump part 246.

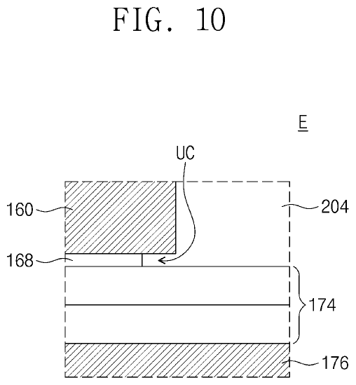

FIG. 9 illustrates an enlarged view showing section A of FIG. 1. FIG. 10 illustrates an enlarged view showing section E of FIG. 9.

Referring to FIGS. 1, 9, and 10, a first seed/barrier pattern 168 may be provided between the first upper pad 160 and the second passivation layer 174. The first seed/barrier pattern 168 may surround bottom and lateral surfaces of the first upper pad 160. For example, the first seed/barrier pattern 168 may cover a bottom surface of the pad part of the first upper pad 160, and may also cover lateral and bottom surfaces of the via part of the first upper pad 160. The first seed/barrier pattern 168 may serve either as a seed layer for forming the first upper pad 160 in fabricating a semiconductor device, or as a barrier layer for preventing diffusion of components between the first upper pad 160 and the second passivation layer 174. The first seed/barrier pattern 168 may include only one of the seed layer and the barrier layer, or may include both of the seed layer and the barrier layer. The seed layer may include gold (Au), silver (Ag), nickel (Ni), tungsten (W), or the like. The barrier layer may include a metal nitride layer or multiple layers of a metal layer and a metal nitride layer. The metal nitride layer may include at least one selected from a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

The first seed/barrier pattern 168 may have an under-cut region UC between the first upper pad 160 and the second passivation layer 174. For example, below the first upper pad 160, the first seed/barrier pattern 168 may have on its lateral surface a shape that is recessed from the lateral surface of the first upper pad 160.

A second seed/barrier pattern 248 may be provided between the second lower pad 240 and the fourth passivation layer 274. The second seedibarrier pattern 248 may surround the lateral and bottom surfaces of the second lower pad 240. For example, the second seed/barrier pattern 248 may cover a top surface (a “top” surface with respect to FIG. 9) of the pad part of the second lower pad 240, and may also cover lateral and top (a “top” surface with respect to FIG. 9) surfaces of the second lower pad 240. The second seed/barrier pattern 248 may serve either as a seed layer for forming the second lower pad 240 in fabricating a semiconductor device, or as a barrier layer for preventing diffusion of components between the second lower pad 240 and the fourth passivation layer 274. The second seed/barrier pattern 248 may include only one of the seed layer and the barrier layer, or may include both of the seed layer and the barrier layer. The seed layer may include gold (Au), silver (Ag), nickel (Ni), tungsten (W), or the like. The barrier layer may include a metal nitride layer or multiple layers of a metal layer and a metal nitride layer. The metal nitride layer may include at least one selected from a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

The second seed/barrier pattern 248 may have an under-cut region between the second lower pad 240 and the fourth passivation layer 274. For example, below the second lower pad 240, the second seed/barrier pattern 248 may have on its lateral surface a shape that is recessed from the lateral surface of the second lower pad 240. The under-cut region of the second seed/barrier pattern 248 may be substantially similar to the under-cut region UC of the first seed/barrier pattern 168 shown in FIG. 10.

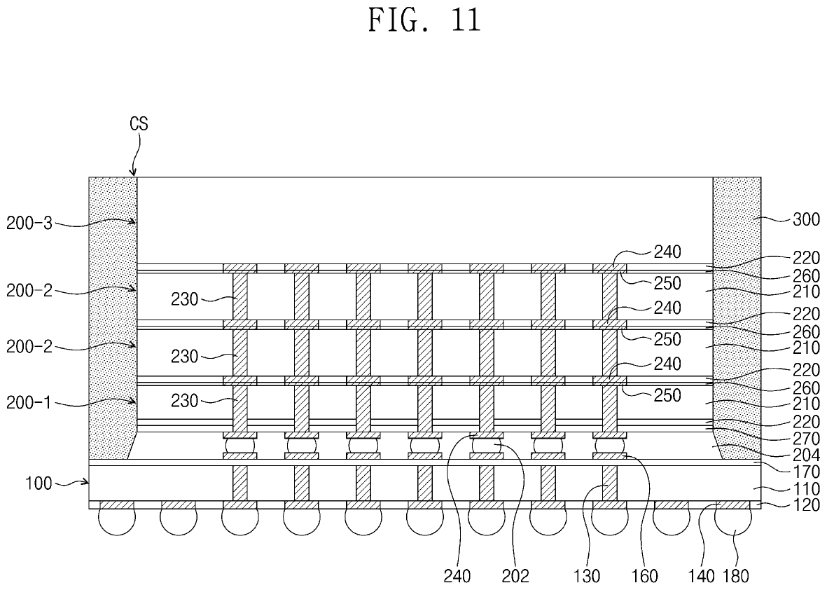

FIG. 11 illustrates a cross-sectional view showing a semiconductor package according to some embodiments of the present disclosure.

Referring to FIG. 11, a base substrate 100 may be provided. The base substrate 100 may be substantially the same as or similar to the base substrate 100 discussed with reference to FIGS. 1 to 10. For example, the base substrate 100 may be a first semiconductor die and may include a first semiconductor substrate 110, a first circuit layer 120 provided on a bottom surface of the first semiconductor substrate 110, a plurality of a first lower pad 140 provided on the bottom surface of the first semiconductor substrate 110 and connected to the first circuit layer 120, a first redistribution layer 170 provided on a top surface of the first semiconductor substrate 110, a plurality of a first through via 130 that vertically penetrate the first semiconductor substrate 110 to connect the plurality of the first lower pad 140 to the first redistribution layer 170, and a plurality of a first upper pad 160 on the first redistribution layer 170. The first redistribution layer 170 may include a first passivation layer 172 (refer to FIGS. 2-3) that covers the top surface of the first semiconductor substrate 110, a first redistribution pattern 176 (refer to FIGS. 2-3) on the first passivation layer 172, and a second passivation layer 174 (refer to FIGS. 2-3) that conformally covers the first passivation layer 172 and the first redistribution pattern 176. The plurality of the first upper pad 160 may pass through openings of the second passivation layer 174 to be coupled to the first redistribution pattern 176, and the openings may each have a pillar shape whose width is constant. An external terminal 180 may be provided on each of the plurality of the first lower pad 140.

A chip stack CS may be disposed on the base substrate 100. The chip stack CS may include one or more semiconductor dies (e.g., a lower semiconductor die 200-1, at least one intermediate semiconductor die 200-2, and an upper semiconductor die 200-3) that are stacked on the base substrate 100. Each of the semiconductor dies may be a memory chip, such as DRAM, SRAM, MRAM, or Flash memory. Alternatively, each of the semiconductor dies may be a logic chip. FIG. 11 depicts that a single chip stack CS is disposed, but embodiments of the present disclosure are not limited thereto. When the chip stack CS is provided in plural, the plurality of the chip stack CS may be spaced apart from each other on the base substrate 100.

The chip stack CS may include a lower semiconductor die 200-1, at least one intermediate semiconductor die 200-2, and an upper semiconductor die 200-3 that are sequentially stacked on the base substrate 100.

The lower semiconductor die 200-1 may be substantially similar to the second semiconductor die 200 discussed with reference to FIGS. 1 to 10. The lower semiconductor die 200-1 may include a second semiconductor substrate 210, a second circuit layer 220, a plurality of a second lower pad 240, and a second redistribution layer 270. In addition, the lower semiconductor die 200-1 may further include a plurality of a second through via 230, a plurality of a second upper pad 250, and an upper passivation layer 260. The plurality of the second upper pad 250 may be disposed on a top surface of the second semiconductor substrate 210, and on the top surface of the second semiconductor substrate 210, the upper passivation layer 260 may surround the plurality of the second upper pad 250. The top surfaces of the upper passivation layer 260 and the plurality of the second upper pad 250 may be substantially coplanar with each other. The plurality of the second through via 230 may vertically penetrate the second semiconductor substrate 210 to connect the plurality of the second lower pad 240 to the plurality of the second upper pad 250.

The at least one intermediate semiconductor die 200-2 may be substantially the same as the lower semiconductor die 200-1 except as, for example, described below. Unlike the lower semiconductor die 200-1, the at least one intermediate semiconductor die 200-2 may not include the second redistribution layer 270. For example, in the at least one intermediate semiconductor, the second circuit layer 220 may be provided on the second semiconductor substrate 210. The plurality of the second lower pad 240 may be portions of a connection pattern exposed on a bottom surface of a dielectric pattern included in the second circuit layer 220. Bottom surfaces of the plurality of the second lower pad 240 and the second circuit layer 220 may be substantially coplanar with each other.

The upper semiconductor die 200-3 may be substantially the same as the at least one intermediate semiconductor die 200-2 except as, for example, described below. Unlike the at least one intermediate semiconductor die 200-2, the upper semiconductor die 200-3 may include none of the second through vias 230, the plurality of the second upper pas 250, and the upper passivation layer 260.

The at least one intermediate semiconductor die 200-2 may be bonded to the lower semiconductor die 200-1. The upper passivation layer 260 of the lower semiconductor die 200-1 and the dielectric pattern of the second circuit layer 220 included in the lowest one from among the at least one intermediate semiconductor die 200-2 may be bonded at an interface between the lower semiconductor die 200-1 and the intermediate semiconductor die 200-2. In this case, the upper passivation layer 260 and the dielectric pattern of the second circuit layer 220 may constitute a hybrid bonding of oxide, nitride, or oxynitride. In this description, the term “hybrid bonding” may denote a bonding in which two components of the same kind are merged at an interface therebetween. For example, a continuous configuration may be formed between the upper passivation layer 260 and its bonded dielectric pattern of the second circuit layer 220, and an invisible interface may be provided between the upper passivation layer 260 and its bonded dielectric pattern of the second circuit layer 220. The upper passivation layer 260 and the dielectric pattern of the second circuit layer 220 may be formed of the same material, and thus no interface may be present between the upper passivation layer 260 and the dielectric pattern of the second circuit layer 220. The upper passivation layer 260 and the dielectric pattern of the second circuit layer 220 may be provided as one component. For example, the upper passivation layer 260 and the dielectric pattern of the second circuit layer 220 may be bonded to each other to constitute a single unitary body. Embodiments of the present disclosure, however, are not limited thereto. The upper passivation layer 260 and the dielectric pattern of the second circuit layer 220 may be formed of different materials from each other. The upper passivation layer 260 and the dielectric pattern of the second circuit layer 220 may have no continuous configuration, and a visible interface may be present between the upper passivation layer 260 and the dielectric pattern of the second circuit layer 220.

The plurality of the second upper pad 250 of the lower semiconductor die 200-1 and the plurality of the second lower pad 240 of the lowest one from among the at least one intermediate semiconductor die 200-2 may be bonded at the interface between the lower semiconductor die 200-1 and the lowest one from among the at least one intermediate semiconductor die 200-2. In this case, the second upper pad 250 and the second lower pad 240 may constitute an intermetallic hybrid bonding therebetween. The second upper pad 250 and the second lower pad 240 that are bonded may have a continuous configuration and may have an invisible interface therebetween. For example, the second upper pad 250 and the second lower pad 240 may be formed of the same material and may have no interface therebetween. Therefore, the second upper pad 250 and the second lower pad 240 may be provided in the form of one component. For example, the second upper pad 250 and the second lower pad 240 may be bonded to constitute a single unitary body.

A bonding between a plurality of the intermediate semiconductor die 200-2 and a bonding between an uppermost one of the plurality of the intermediate semiconductor die 200-2 and the upper semiconductor die 200-3 may be substantially the same as the formerly described bonding between the lower semiconductor die 200-1 and the lowermost one of the plurality of the intermediate semiconductor die 200-2.

The chip stack CS may be mounted on the base substrate 100. The chip stack CS may be disposed on the base substrate 100. The plurality of the first upper pad 160 of the base substrate 100 may be vertically aligned with the plurality of the second lower pad 240 of the lower semiconductor die 200-1. A plurality of a die connection terminal 202 may be provided between the plurality of the first upper pad 160 and the plurality of the second lower pad 240. The plurality of the die connection terminal 202 may connect the plurality of the first upper pad 160 to the plurality of the second lower pad 240.

An underfill layer 204 may be provided between the base substrate 100 and the chip stack CS. The underfill layer 204 may fill a space between the base substrate 100 and the lower semiconductor die 200-1. The underfill layer 204 may surround the die connection terminal 202.

The base substrate 100 may be provided thereon with a molding layer 300 that covers the chip stack CS. The molding layer 300 may protect the chip stack CS. The molding layer 300 may include a dielectric material. For example, the molding layer 300 may include an epoxy molding compound (EMC).

In a semiconductor package according to some embodiments of the present disclosure, a small thickness may be given to passivation layers used as a backside redistribution layer of a semiconductor die. For example, the thickness of the passivation layers may be less than a thickness of a redistribution pattern of the redistribution layer. Therefore, heat shielding by the passivation layers may be less likely to occur in the semiconductor package, heat generated from the semiconductor die may easily be discharged upwards from the semiconductor die, and heat generated from another semiconductor die positioned on the semiconductor die may easily be discharged downwards through the semiconductor die. In addition, it may be possible to provide a thin compact-sized semiconductor package.

A via part of an upper pad on the redistribution layer may have either a pillar shape whose width is constant, or a tapered pillar shape whose lateral surface has a small inclination angle. Therefore, there may be no or negligible difference in width between a bottom surface of the via part in contact with the redistribution pattern and a top surface of the via part in contact with a pad part, and the upper pad may have a small width. Accordingly, the upper pad may have an occupied area, and the semiconductor package may have a compact size, an increased wiring density, and improved electrical properties.

As one of the passivation layers that covers the redistribution pattern is provided to have a small thickness and to conformally cover the redistribution patterns, the redistribution patterns may be provided to have a small interval therebetween, and the upper pads may be provided to have a small interval therebetween. Therefore, the semiconductor die may have an increased wiring density, and the semiconductor package may have a compact size.

Although non-limiting example embodiments of the present disclosure have been described in connection with the accompanying drawings, it will be understood by one of ordinary skill in the art that variations in form and detail may be made therein without departing from the spirit and of the present disclosure. The above described example embodiments should thus be considered illustrative and not restrictive.

What is claimed is:

1. A semiconductor package, comprising:
a first semiconductor die; and
a second semiconductor die on the first semiconductor die,
wherein the first semiconductor die comprises:
a semiconductor substrate;
a wiring layer on an active surface of the semiconductor substrate;
a redistribution pattern on an inactive surface of the semiconductor substrate;
a first passivation layer on the inactive surface of the semiconductor substrate, wherein the first passivation layer is on the redistribution pattern and has an opening that exposes a top surface of the redistribution pattern; and
a backside pad on the first passivation layer and coupled through the opening to the redistribution pattern,
wherein an inner lateral surface of the opening is inclined at an angle of 90 degrees to 105 degrees relative to the top surface of the redistribution pattern, and
wherein a thickness of the first passivation layer is 0.3 times to 0.5 times a thickness of the redistribution pattern.

2. The semiconductor package of claim 1, wherein the first passivation layer comprises multiple layers.

3. The semiconductor package of claim 2, wherein the multiple layers of the first passivation layer comprise a silicon nitride layer and a silicon oxide layer.

4. The semiconductor package of claim 1, wherein a width of the opening is in a range of 1 μm to 10 μm.

5. The semiconductor package of claim 1, wherein the thickness of the first passivation layer is constant on the semiconductor substrate.

6. The semiconductor package of claim 5, wherein the thickness of the first passivation layer is in a range of 0.5 μm to 2 μm.

7. The semiconductor package of claim 1, wherein the first semiconductor die further comprises a second passivation layer that is on the inactive surface of the semiconductor substrate,
wherein the redistribution pattern is on the second passivation layer, and
wherein, on the second passivation layer, the first passivation layer is on the redistribution pattern.

8. The semiconductor package of claim 7, wherein the second passivation layer comprises multiple layers.

9. The semiconductor package of claim 8, wherein the multiple layers of the second passivation layer comprise a silicon nitride layer and a silicon oxide layer.

10. The semiconductor package of claim 1, wherein the second semiconductor die is mounted on the first semiconductor die by a die connection terminal on the backside pad of the first semiconductor die.

11. The semiconductor package of claim 1, wherein the first semiconductor die further comprises a plurality of through vias that vertically penetrate the semiconductor substrate and are coupled to the redistribution pattern.

12. The semiconductor package of claim 1, further comprising:
a plurality of external terminals on a front surface of the first semiconductor die:
an underfill layer that fills a space between the first semiconductor die and the second semiconductor die; and
a molding layer on the first semiconductor die, wherein the molding layer surrounds the second semiconductor die in a horizontal direction of the semiconductor package.

13. The semiconductor package of claim 1, wherein the first semiconductor die further comprises a seed layer between the backside pad and the first passivation layer,
wherein, below the backside pad, the seed layer has an under-cut region that is recessed from a lateral surface of the backside pad.

14. A semiconductor package, comprising:
a first semiconductor die comprising:
a semiconductor substrate:
a plurality of through vias that vertically penetrate the semiconductor substrate;
a plurality of redistribution patterns on a rear surface of the semiconductor substrate and connected to the through vias:
a first passivation layer on the rear surface of the semiconductor substrate and on the plurality of redistribution patterns; and
a plurality of pads on the first passivation layer:
a second semiconductor die on the first semiconductor die, wherein the second semiconductor die is mounted on the plurality of pads;
a molding layer on a rear surface of the second semiconductor die, wherein the molding layer surrounds the second semiconductor die in a horizontal direction of the semiconductor package; and
a plurality of external terminals on a front surface of the first semiconductor die,
wherein each of the plurality of pads comprises:
a pad part on the first passivation layer; and
a via part that extends from a bottom surface of the pad part and penetrates the first passivation layer such as to connect with a respective one of the plurality of redistribution patterns,
wherein the via part has a pillar shape that has a width that is constant, and
wherein the first passivation layer comprises a silicon nitride layer and a silicon oxide layer.

15. The semiconductor package of claim 14, wherein a thickness of the first passivation layer is 0.3 times to 0.5 times a thickness of the plurality of redistribution patterns.

16. The semiconductor package of claim 14, wherein the width of the via part is in a range of 1 μm to 10 μm.

17. The semiconductor package of claim 14, wherein a thickness of the first passivation layer is constant on the semiconductor substrate.

18. The semiconductor package of claim 14, wherein the first semiconductor die further comprises a second passivation layer that is on the rear surface of the semiconductor substrate,
wherein the plurality of redistribution patterns are on the second passivation layer, and
wherein, on the second passivation layer, the first passivation layer is on the plurality of redistribution patterns.

19. The semiconductor package of claim 18, wherein the second passivation layer comprises a silicon nitride layer and a silicon oxide layer.

20. A semiconductor package, comprising:
a first semiconductor die; and
a second semiconductor die on the first semiconductor die,
wherein the first semiconductor die comprises:
a semiconductor substrate:
a wiring layer on an active surface of the semiconductor substrate;
a first passivation layer on an inactive surface of the semiconductor substrate:
a redistribution pattern on the first passivation layer:
a second passivation layer on the first passivation layer, the second passivation layer on the redistribution pattern and having an opening that exposes a top surface of the redistribution pattern; and
a backside pad on the second passivation layer and coupled through the opening to the redistribution pattern,
wherein a thickness of the second passivation layer is less than a thickness of the redistribution pattern,
wherein the thickness of the second passivation layer is constant on the semiconductor substrate, and
wherein the second passivation layer comprises a silicon nitride layer and a silicon oxide layer.
